(19) United States
(12) Patent Application Publication
(10) Pub. No.: US 2011/0051346 A1
(43) Pub. Date: Mar. 3, 2011

(54) MULTI-FUNCTIONAL HANDHELD DEVICE HAVING MOVEABLE SEGMENTS

(76) Inventor: Huy Nguyen, San Jose, CA (US)

(21) Appl. No.: 12/856,275

(22) Filed: Aug. 13, 2010

Related U.S. Application Data
(63) Continuation of application No. 10/159,518, filed on May 31, 2002.

(51) Int. Cl. G06F 1/16; H05K 7/00

(52) U.S. Cl. 361/679.09; 361/679.01; 361/679.3; 361/679.56

(57) ABSTRACT

A handheld computer is provided that includes a first module combined with one or more modules. The first module includes a housing having one or more coupling surfaces, with each coupling surface including a coupling mechanism. A second module is coupleable to the first module. The second module includes a third coupling surface having a second coupling mechanism for mating with the first coupling mechanism. The third coupling surface is positioned on the second module so as to abut at least partially against the second coupling surface when the first coupling mechanism is mated with the second coupling mechanism.

### RELATED APPLICATIONS

This application is a continuation of U.S. patent application Ser. No. 10/159,518, filed May 31, 2002, and the aforementioned application is hereby incorporated by reference.

### FIELD OF THE INVENTION

The present invention relates to handheld devices. In particular, the present invention relates to a multi-functional handheld device having moveable segments.

### BACKGROUND OF THE INVENTION

Handheld devices are used for a variety of applications. Such devices include, for example, personal digital assistants (PDAs), cellular phones, digital audio playback devices, and digital cameras. In general, small sizes are desired for handheld devices to enhance mobility.

With the advancement of technology, the functionality that can be provided by handheld devices has increased dramatically. For example, PDA's may be equipped with MP3 players, or outfitted with external cards that can be used to enable image capturing.

Even with the functional enhancements to such devices, size is a primary consideration. Often, the size of the handheld device is limited by the various hardware components that are used to operate the various functional features of the handheld device. For example, keyboards on PDAs must at least accommodate a user's fingers, so some portion of the available exterior surface on the handheld device must be of a minimum size to enable a keyboard that is usable. Several mechanisms have been developed to minimize the overall size of the handheld device while promoting additional functionality from the handheld device.

Sometimes the functionality from two different devices is combined into one unit. But combining devices such as handheld computers with other devices generally leads to a device that is larger than a device having the functionality of only one device. Usually, this is because each type of device has a particular set of hardware features that are exposed on the device. The physical presence of hardware features for each type of device cannot be eliminated when two or more different types of devices are combined.

### SUMMARY OF THE INVENTION

Embodiments of the invention provide for a handheld device having different functional components distributed on a moveable or folding housing that reduces the overall size of the handheld device.

In an embodiment, a handheld device includes a housing having two or more segments and a plurality of exterior surfaces. The segments of the housing are moveably coupled to one another. A processor is configured to execute a plurality of applications, including a first application associated with a first set of hardware devices, and a second application associated with a second set of hardware devices. The handheld computer is configured to be held by a user so as to orient one of the plurality of exterior surfaces towards a user. The first segment and the second segment can be positioned so that a first exterior surface in the plurality of exterior surfaces can be oriented towards the user so as to favor the use of the first set of hardware devices in conjunction with execution of the first application. The second exterior surface in the plurality of exterior surfaces can be oriented towards the user so as to favor the use of the second set of hardware devices in conjunction with execution of the second application.

### BRIEF DESCRIPTION OF THE DRAWINGS

Embodiments of the invention are illustrated by way of example, and not by way of limitation, in the figures of the accompanying drawings. Like reference numerals are intended to refer to similar elements among different figures.

FIG. 1 is a frontal view of a handheld device 100 having a housing 105 in a fully extended position.

FIG. 2 is a frontal view of a handheld device in a first contracted position.

FIG. 3 is a frontal view of a handheld device in a second contracted position.

FIG. 4 is a side view of a handheld device in one of two possible contracted positions.

FIGS. 5A-5D illustrate one of the first or second segment pivoting about the other of the first or second segment, under an embodiment of the invention.

FIG. 6 is an isometric view of a handheld device, under another embodiment of the invention.

FIG. 7 is an isometric view of a handheld device illustrating components on another exterior surface, under another embodiment of the invention.

FIG. 8 is an isometric view of a handheld device in a contracted position, under another embodiment of the invention.

FIG. 9 is a method for operating a multi-functional handheld device, under an embodiment of the invention.

FIG. 10 is a block diagram of an handheld device for use with an embodiment of the invention.

### DETAILED DESCRIPTION OF THE INVENTION

Embodiments of the invention describe a multi-functional handheld device with moveable segments. In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

A. Overview

A multi-functional device is provided that can be rotated, or manipulated in its configuration, in order to favor the use of the handheld device for a particular function. In one embodiment, the handheld device combines the functionality of a PDA type device, with the functionality of other digital handheld devices. In addition to use of the handheld device as a PDA, specific examples of functions that can be integrated into the handheld device include one or more of the following functionalities: audio playback device, audio recorder, wireless voice and/or data communication device, digital camera, video recorder, and global positioning system.

According to an embodiment of the invention, a multi-functional handheld device is provided having a housing separated into a first segment and a second segment. The first segment and the second segment combine to provide the handheld device a plurality of exterior faces. The exterior faces extend substantially a length of one of the first segment or the second segment. A first set of features is provided on the a first exterior face. The first set of features are operable to cause the handheld device to input or output audio. A second set of features are provided on a second one of the exterior faces. The second set of features include at least a display. At least some of the features in the second set of features are operable to select content four output on the display. A third set of features are provided on a third one of the exterior faces. The third set of features are operable to cause the handheld device to capture an image.

According to embodiments of the invention, housing segments may be connected to one another so that one segment can pivot, rotate, or slide with respect to the other segment.

Other embodiments may provide different sets of features for functionalities other than playing back audio, selecting display content, and capturing images. For example, features for recording audio, enabling wireless communications (voice or data), and alternate input mechanisms (keyboard, handwriting recognition) may be provided on different exterior surfaces provided by the housing segments. Other examples are provided elsewhere in this application.

An external face of one of the housing segments is an external region of the handheld device that extends primarily in one direction. The faces may be substantially flat, or slightly arched. The face may correspond to the exterior surface of a panel or other housing component used to form the individual segments.

A “feature” is any logical component, including hardware, software and firmware, for causing the handheld device to perform functions or operations.

As used herein, the term “substantially” means 90% or more of a referenced quantity.

According to another embodiment, a handheld device includes a first housing segment, and a second housing segment moveably connected to the first housing segment. The first housing segment and the second housing segment combine to provide a plurality of exterior surfaces. A plurality of hardware devices are disposed on the exterior surfaces. A processor of the handheld device is configured to execute a plurality of applications, including at least a first application that is associated or designated for use with the first set of hardware devices, and a second application that is associated or designated for use with the second set of hardware devices. The handheld device is configured so as to be held by a user so as to orient one of the plurality of exterior surfaces towards the user. The first housing segment and the second housing segment can be positioned relative to one another so that a first exterior surface can be oriented towards the user so as to favor the use of the first set of hardware devices in conjunction with execution of the first application, and so that a second exterior surface can be oriented towards the user so as to favor the use of the second set of hardware devices in conjunction with execution of the second application.

Use of the term “favor” is intended to mean that the location and/or orientation of an identified component of the handheld computer makes that component easier to use under normal conditions than another component not similarly situated, assuming that the handheld device is being operated in an ordinary fashion.

Examples of specific types of applications that can be associated with hardware devices of the handheld device include audio playback applications, audio recording applications, camera applications (such as applications for capturing still images or for video recording), GPS applications, and wireless communication applications. Wireless communication applications may include applications for voice communications, as well as applications for receiving or sending data over wireless networks, such as through BlueTooth or other radio-frequency mediums.

Several advantages are provided by embodiments of the invention. Among the advantages, a handheld device is provided that is capable of performing various functions, each of which require surface area on the handheld device. The handheld device provides the surface area for such input and output devices, but maintains a relatively small overall dimension for the handheld device.

B. Configurations for Handheld Computer with Moveable Segments

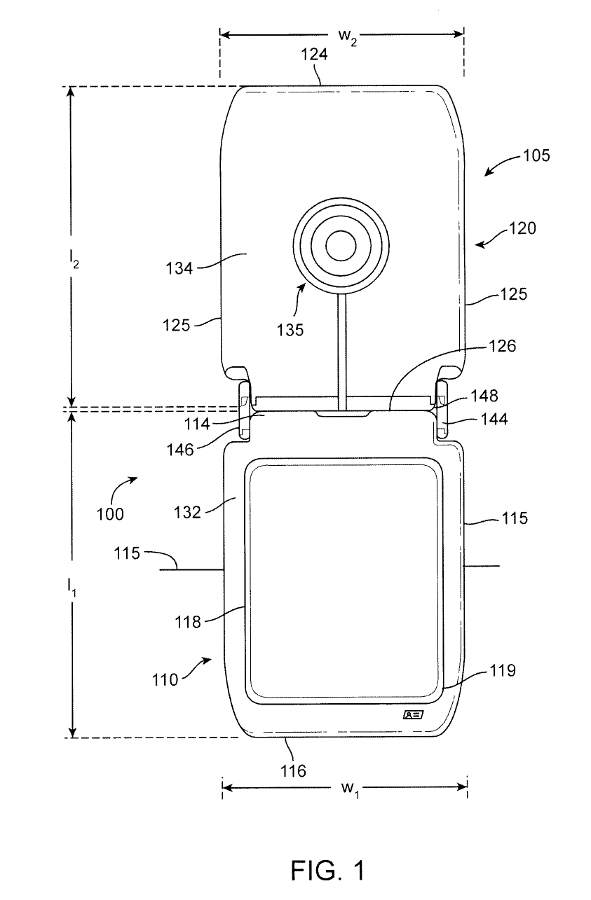

FIG. 1-4 illustrate different views of a multi-functional handheld device with moveable housing segments, under an embodiment of the invention. According to an embodiment described, a handheld device 100 includes features for operating the device as a PDA, a music playback device, and a digital camera. Features for operating handheld device 100 as one of these three types of devices are provided on different exterior surfaces of the handheld device.

FIG. 1 is a frontal view of a handheld device 100 having a housing 105 in a fully extended position. The first segment 110 and second segment 120 are pivotably coupled to one another so that the first segment 110 can be moved between contracted and extended positions. Moving the first segment 110 and second segment 120 facilitates use of different features or hardware components for performing specific functions. In an embodiment such as shown by FIG. 1, an extended state corresponds to second segment 120 being pivoted about first segment 110 so that first segment 110 and second segment 120 are about coplanar.

According to one embodiment, first segment 110 includes a first exterior surface 132, a top end 114 and a bottom end 116, and a pair of lateral sides 115. A length l1 extends between top end 114 and bottom end 116 of first segment 110. A width w1 extends between lateral sides 115 of first segment 110. A first set of hardware devices are disposed so as to be accessible on the first exterior surface 132.

The second segment 120 includes a second exterior surface 134, a top end 124, and a bottom end 126. A length l2 extends between top end 124 and bottom end 126 of second segment 120. A width w2 extends between lateral sides 125 of first segment 120.

The bottom end 126 of the second segment 120 is pivotably connected to the top end 114 of first segment 110. A frontal view of first segment 110 and second segment 120 shows that the first exterior surface 132 and second exterior surface may be aligned, or otherwise viewable to a user at the same time. When handheld device 100 is in the extended position, the overall length of the handheld device may range somewhere between l1 and l1+l2. For example, handheld device 100 may be fully extendable so that the overall length of the device is l1+l2.

In an embodiment, the first set of hardware devices are used to operate handheld device 100 as a PDA. The first set of hardware devices may include a touch-sensitive display 118, and an alphanumeric input area 119. The alphanumeric input area 119 may be used to enter input, and to select content that is displayed on display 118. The display 118 may be contacted to select content appearing on it, and to enter input.

In the example shown, alphanumeric input area 119 is a handwriting recognition area, such as provided by GRAFFITI in the PALM OS (manufactured by PALM INC.). Other types of alphanumeric input areas include keyboards. Actuation keys (not shown in FIG. 1) be may used to launch applications, and to select input or content appearing on display 118. Examples of applications that may be launched or otherwise operated by a PDA type device include personal information management (PIM) applications, including calendar applications for maintaining appointments, address book applications for maintaining contact information, to-do applications to maintain lists, and memo applications to allow entries of memos. Other applications that may be used by a PDA type device include word processing applications, graphic applications for jotting illustrations, and spreadsheets. A PDA type device is any device that operates such applications, or that is able to receive alphanumeric input.

In an embodiment, the second set of hardware devices may be used to operate handheld device 100 as a digital camera, or other device that captures images. Accordingly, the second set of hardware devices may include a lens 135 for using handheld device 100 as a digital camera.

In one embodiment, first segment 110 and second segment 120 may be pivotably connected to one another by a first hinge element 144 and a second hinge element 146. The first and second hinge elements 144, 146 may extend from the top end 114 of first segment 110 and bottom end 126 of second segment 120. The hinge elements 144, 146 may carry electrical connectivity between first segment 110 and second segment 120. The hinge elements 144 and 146 enable first segment 110 and second segment 120 to pivot relative to one another between the fully-extended position and one or more contracted positions.

As will be described, other exterior surfaces of handheld device 100 may carry features or hardware devices for operating other functions of the handheld device. For example, an exterior surface opposing second exterior surface 134 on second segment 120 may carry hardware components for enabling the handheld device 100 to playback audio files.

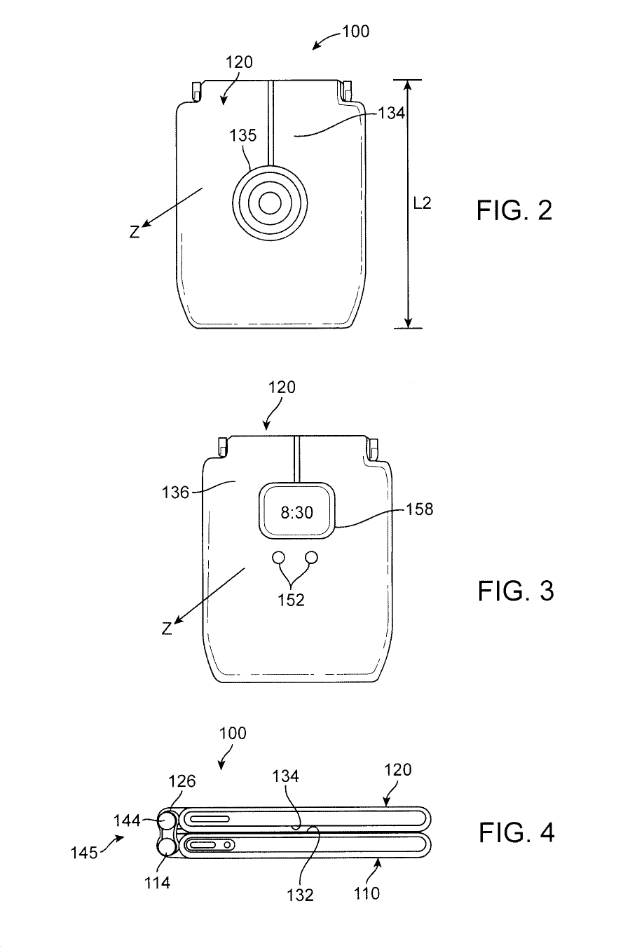

FIG. 2 is a frontal view of handheld device 100 in a first contracted position. In the example shown, the first contracted position corresponds to second segment 120 being pivoted so that second exterior surface 134 is outwardly oriented to overlay first exterior surface 132. In this configuration, the lens 135 is directed in a first direction of intersecting axis Z. The display 118 may be directed in the opposite direction of axis Z (extending orthogonally with respect to the paper).

In the first contracted position, the overall length of handheld device 100 is reduced to the longer length of the two segments. In the example provided, the two segments are shown to be of equal length, thus the length of the contracted position may be assumed to be l1 or l2. The second exterior surface 134 extends all of, or at least a substantial length of, second segment 120. The overall width of the device is also the longer of the width of the two segments, which for simplicity is shown to be the same.

FIG. 3 is a frontal view of handheld device 100 in a second contracted position. In the second contracted position, second segment 120 may be flipped nearly 180 degrees with respect to first segment 110. In this configuration, a third exterior surface 136 is outwardly oriented to be adjacent to first exterior surface 132. However, in the second contracted position, third exterior surface 136 and first exterior surface 132 are oriented in the same direction of axis Z (extending orthanormally with respect to the paper).

A third set of hardware components may be provided on third exterior surface 136. In an embodiment, the third set of hardware components may be for enabling a user to control playback of audio, recorded in a digital format. Thus, the third set of hardware components may correspond to mechanical and software user-interface features for signaling handheld device 100 to playback audio, volume control, menu and record selection, as well as numerous other examples. In the example provided by FIG. 3, mechanical buttons 152 may be disposed on third exterior surface 136 along with a display 158 that indicates a status of the media playback. An audio jack (not shown in FIG. 3) may also be disposed on third exterior surface 136.

FIG. 4 is a side view handheld device 100 in one of two possible contracted positions, under an embodiment of the invention. In either contracted position, one of the exterior surfaces of first segment 110 is adjacent to one of the exterior surfaces of second segment 120. For example, second exterior surface 134 may be adjacent to first exterior surface 132. The term adjacent in this context means that two proximate exterior surfaces are in contact, or close to it, so that the two exterior surfaces are about parallel.

FIG. 4 illustrates a hinge 145 that pivotably connects the first segment 110 to second segment 120. The hinge 145 may be formed by hinge members 144, 146 extending along one lateral side between the top 114 of first segment 110 and the bottom end 126 of second segment 120 (see FIG. 1). The hinge 145 allows for the first segment 110 and second segment 120 to be moveably connected so as to allow a pivoting or rotating motion of one of the segments about the other segment.

With embodiments described by FIGS. 1-4, some or all of the hardware components and features described on each of the exterior surfaces 132, 134, 136 may be located on other surfaces. For example, side panels or external surfaces between second and third exterior surface 134 and 136 may be used to carry an audio jack.

C. Movement of Segments

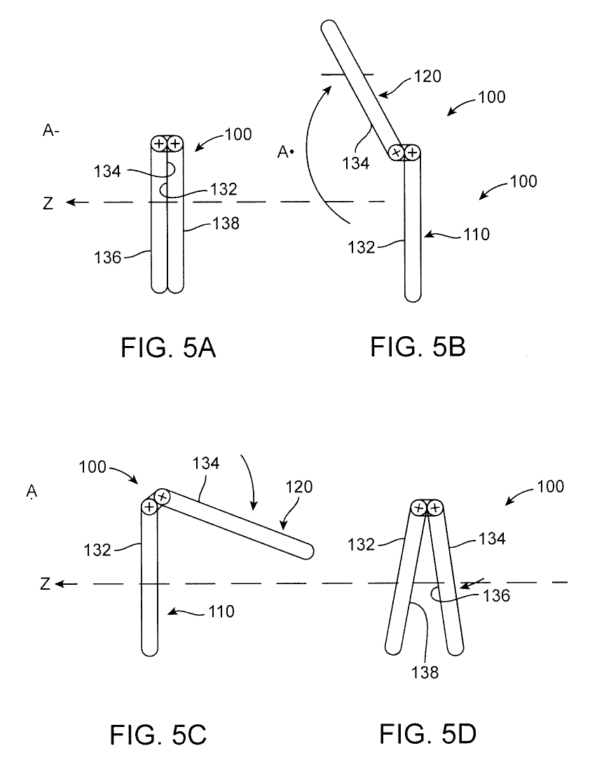

FIGS. 5A-5D illustrate one of the first or second segments 110, 120 pivoting about the other of the segments, under an embodiment of the invention. For purpose of description, first segment 110 is assumed to be on the bottom, and second segment 120 is assumed to be on top and rotating about first segment 110.

FIG. 5A is a side view illustrating the first contracted position for handheld device 100. In the first contracted position, third exterior surface 136 is oriented towards a first direction of axis Z, and a fourth exterior surface 138 is oriented towards a second direction of axis Z. In FIG. 5A, handheld device 100 is oriented so that user, indicated by reference point A, favors use of third exterior surface 136. The hardware components and features of third exterior surface 136 may be favored because the third exterior surface 136 is oriented towards the user at reference point A, and also because the third exterior surface is proximate to reference point A.

In the example shown for the first contracted position, first exterior surface 132 and the second exterior surface 134 are positioned adjacent to one another. In the implementation shown, fourth exterior surface 138 may include openings or attachment mechanisms for enabling the mechanical attachment of an external device to handheld device 100. Alternatively, fourth exterior surface 138 may include another set of hardware devices, which may be used for other functions of handheld device 100.

In one embodiment, the configuration shown in FIG. 5A may correspond to handheld device 100 being used as a music playback device. The hardware components of the media playback device are provided on the third surface 136. The other components of handheld device 100 are folded onto one another so as to not interfere with the user's operation of the media playback device.

FIG. 5B is a side view illustrating a partially extended position for handheld device 100. The second segment 120 may be pivoted about first segment 110 so as to separate first exterior surface 132 and second exterior surface 134. In this position, hardware components and features of both first exterior surface 132 and second exterior surface are accessible to the user in the direction of reference point A. The hardware components and features of third exterior surface 136 are not readily accessible to the user from reference point A.

A configuration such as shown by FIG. 5B may favor use of handheld device 100 as either a PDA type device or an image capturing device. For example, a wireless video conferencing application may be provided for the handheld device 100 as the configuration for the device may include hardware for capturing an image on second exterior surface 134, and hardware for displaying an image on first exterior surface 132.

FIG. 5C is a side view illustrating a partially contracted position for handheld device 100. In this position, first exterior surface 132 is primarily accessible to the user at reference point A. The third exterior surface 136 is the least accessible.

FIG. 5D is a side view illustrating a second contracted position for handheld device 100. In this position, first exterior surface 132 is favored because it is oriented towards reference point A, along axis Z. Second exterior surface 134 is oriented substantially in the opposite direction along the axis Z. The third and fourth exterior surfaces 136 and 138 are interior and adjacent to one another.

This configuration may correspond to a tri-pod position for handheld device 100. In the tri-pod position, the first exterior surface 132 and second exterior surface 134 are available. The first segment 110 and second segment 120 can support the handheld device 100 in an upright position. This may have particular use for image capturing functionality, where second exterior surface 134 provides lens 135.

D. Alternative Construction

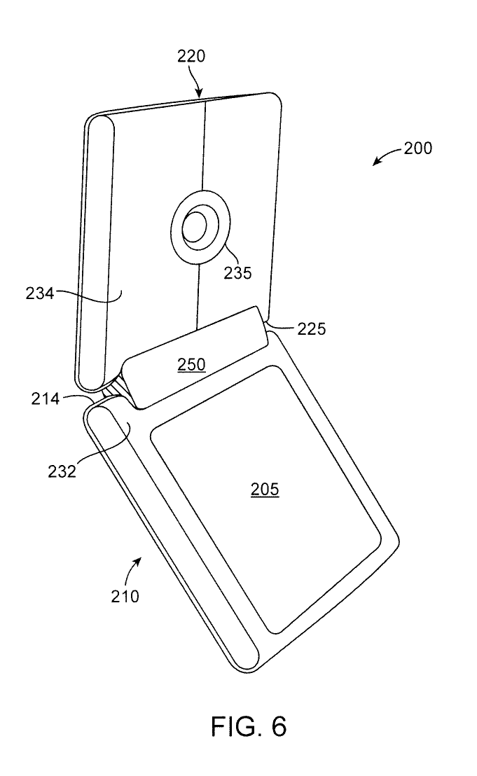

FIGS. 6-8 illustrate alternative constructions for a handheld device. In addition, a handheld device such as shown by FIGS. 6-8 may include components and features for different functions.

FIG. 6 is an isometric view of a handheld device 200 in an extended position. A first segment 210 is pivotably connected to a second segment 220 by a hinge body 250. A top end 214 of first segment 210 is connected to hinge body 250 to enable the first segment to pivot about the hinge body. A bottom end 225 of second segment 220 is connected to hinge body 250 to enable the second segment to pivot about the hinge body. A flex circuit 255 (not shown) extends electrical connectivity between components of first segment 210 and components of second segment 220.

According to an embodiment such as shown by FIG. 6, a first exterior surface on first segment 210 includes a screen 205. A second exterior surface 234 on second segment 220 includes a lens 235, to be used with image capturing logic internal to handheld device 200. The screen 205 may output images captured using lens 235 and the internal image capturing logic. For example, lens 235 and screen 205 may be positioned so that a user at reference point B can use handheld device 200 for mobile video conferencing.

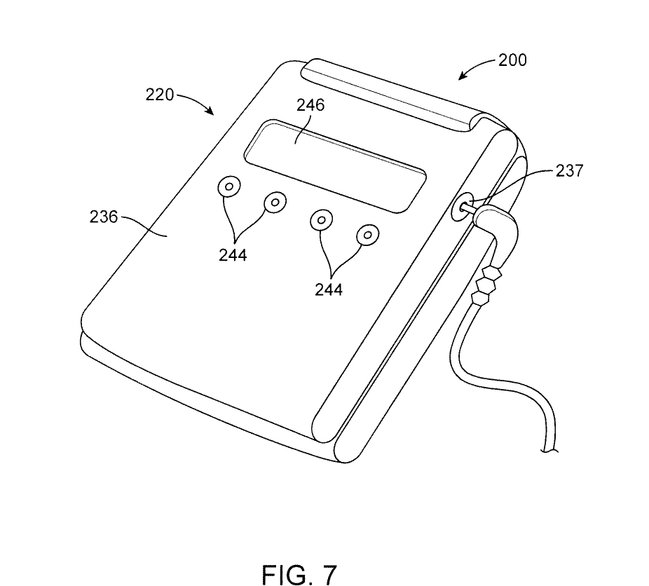

FIG. 7 is an isometric view of a third exterior surface 236 on the second segment 220 of handheld device 200. The third exterior surface 236 may include hardware components and features for audio playback of digitally recorded sounds, such files recorded in the MP3 format. The components on third exterior surface 236 include buttons 244 and a screen 246 to indicate a playback status. An audio jack 237 may be incorporated into one of the surfaces extending between the second and third exterior surfaces 234 and 236.

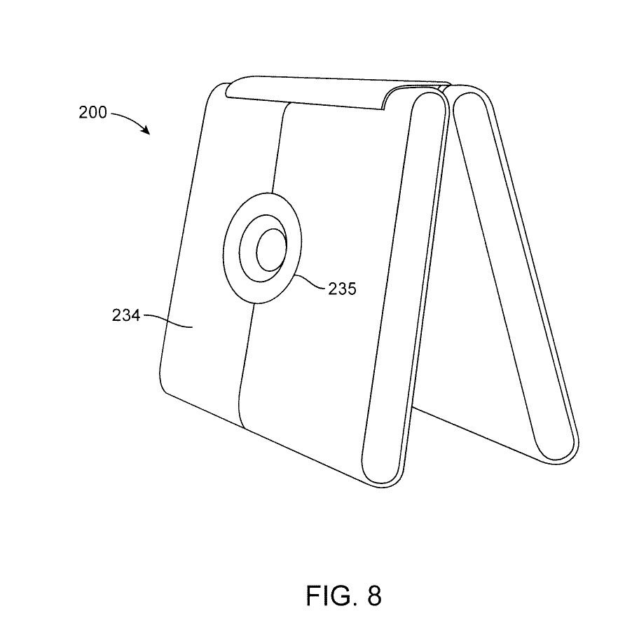

FIG. 8 is a side isometric view of handheld device 200 in another contracted position with lens 235 facing outward on exterior surface 234. The screen 205 on first exterior surface 232 may face the other direction.

Several other mechanisms may be used to enable a housing construction where moveably connected housing segments are used to provide exterior surfaces where components and surface features may be disposed. For example, U.S. application ser. No. 09/932,213, entitled HANDHELD COMPUTER HAVING MOVEABLE SEGMENTS THAT CAN BE ADJUSTED TO AFFECT A SIZE OF THE HANDHELD COMPUTER, filed Aug. 17, 2001, and naming William Webb et al. as inventors, hereby incorporated by reference in its entirety, illustrates another way in which a handheld computer may be constructed to have moveable housing segments. Another exemplary housing construction having moveable segments for use with embodiments of the invention is disclosed in U.S. patent application Ser. No. 10/006,537, entitled INTEGRATED HANDHELD DATA PROCESSING DEVICE HAVING A SLIDING FORM FACTOR, filed Nov. 30, 2001, and naming Huy Nguyen and Lawrence Lam as inventors, the aforementioned patent application being hereby incorporated by reference in its entirety.

E. Method for Operating Handheld Device

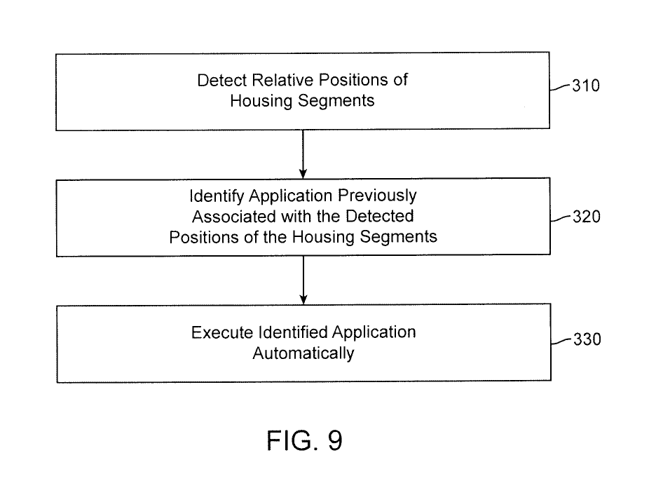

FIG. 9 is a method for operating a multi-functional handheld device, under an embodiment of the invention. According to an embodiment, one or more applications may be launched on a handheld device in response to a processor of the handheld device detecting a relative position of the first segment 110 (FIG. 1) and second segment 120 (FIG. 1). Reference to numerals in other figures is intended to show exemplary components for practicing an embodiment of the invention.

In step 310, a relative position of first segment 110 and second segment 120 is detected. A sensor or other similar device that can obtain relative position information between first segment 110 and second segment 120. As an alternative, changes in the relative position of the first segment 110 and second segment 120 may detected, rather than the actual positions of the two segments.

In step 320, an application previously associated with the detected relative position of the first segment 110 and second segment 120 is identified. The application may, for example, be one for operating handheld device 100 as a music playback device, as a digital camera, or as a video conferencing device.

In step 330, the identified application is executed automatically. Thus, for example, when the relative position of first segment 110 and second segment 120 corresponds to that shown in FIG. 5A, an audio playback application may be executed by the processor of handheld device 100. As another example, when the relative position of first segment 110 and second segment 120 corresponds to that shown in FIG. 5B, a video conferencing application may be executed by the processor of handheld device 100.

F. Hardware Diagram

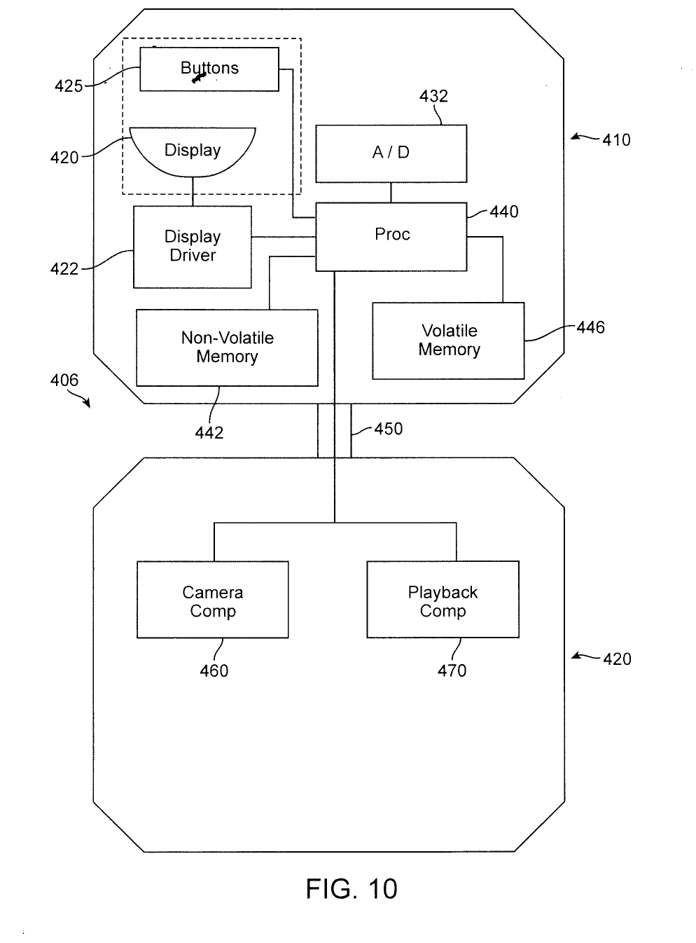

FIG. 10 is a block diagram of a handheld device 400 for use with an embodiment of the invention. The handheld device 400 may be separated into a first portion 410 and a second portion 440, corresponding to first segment 110 and second segment 120 in FIGS. 1-4. Each portion may be electrically connected through a connector, such as a flex circuit 450.

In an embodiment, handheld computer includes a processor 440 coupled to a first memory 444 (non-volatile) and a second memory 446 (volatile). The processor 440 is coupled to a display driver 422. The processor 440 combines with display driver 422 to process and signal data for presentation on a display assembly 420. The display assembly 420 includes screen and digitizer. A set of buttons 425 or other actuation mechanisms may be connected to signal interrupts or other actuation signals to processor 440.

An analog-digital (AD) converter 432 is coupled to processor 440. One or more channels from A/D converter 432 maybe used to convert analog input provided by the digitizer, or by another analog input mechanism.

The processor 440 may be electrically connected to one or more set of components on second portion 420 via flex connector 450. In an example shown, a set of camera components 460 and a set of playback components 470 may be connected to processor 440. The set of camera components 460 may include, for example, a lens, light-detecting sensors, and circuitry to send signals corresponding light being detected. The set of playback components 470 may include, for example, speakers.

The hardware devices designed to appear on the surface of handheld device 400 may be provided on separate external surfaces formed by the different housing segments of the handheld device 100. For example, in one embodiment, a lens from the set of camera components 460 may be provided on one exterior surface; buttons, speakers and other user-interface features from the media playback component 470 may be provided on another exterior surface; and the display 420 and buttons 425 may be provided on still another exterior surface.

G. Conclusion

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense.

What is claimed is:

1. A multi-functional handheld device comprising:
a housing separated into a first segment and a second segment, the housing including a plurality of exterior faces, including at least a first face, a second face, and a third face that each extend substantially a length of one of the first segment or the second segment;
a first set of features provided on the first face, the first set of features being being operable to cause the handheld device to input or output audio;
a second set of features provided on the second face, the second set of features including at least a display, at least some of the features in the second set of features being operable to select content for output on the display; and
a third set of features provided on the third face, the third set of features being operable to cause the handheld device to capture an image.

2. The handheld device of claim 1, wherein the second segment is pivotably one side of the first segment so as to extend at least between a first contracted position and an extended position.

3. The handheld device of claim 1, wherein the second segment is pivotably connected to one side of the first segment so as to extend between at least a first contracted position and a second contracted, wherein in the first contracted position, one of the plurality of faces that is provided by the first segment is adjacent to one of the plurality of faces that is provided by the second segment, and wherein in the second contracted position, another one of the plurality of faces that is provided by the first segment is adjacent to another one of the plurality of faces that is provided by the second segment.

4. The handheld device of claim 3, wherein when the handheld device is in one of the first contracted position or the second contracted position, the second set of features is at least substantially enclosed so that the second set of features is inaccessible to contact by a user.

5. The handheld device of claim 1, wherein the first set of features includes at least one of a speaker or a microphone.

6. The handheld device of claim 1, wherein the second set of features includes a plurality of actuation keys, and wherein the display is touch-sensitive.

7. The handheld device of claim 1, wherein the third set of features includes a lens.

8. The handheld device of claim 1, further comprising a hinge to pivotably connect the first segment to the second segment

9. The handheld device of claim 1, further comprising a processor configured to execute instructions for inputting and outputting audio, for outputting content on the display, and for capturing images.

10. The handheld device of claim 9, wherein the processor is configured to launch an application associated with at least one of the first set of features, the second set of features, and the third set of features in response to detecting a relative position of the first segment and the second segment.

11. The handheld device of claim 9, wherein the processor is configured to detect an input entered through at least one of the first set of features, the second set of features, and the third set of features, and to launch an application associated with the at least one of the first set of features, second set of features, and third set of features that is used to enter the input.

12. The handheld device of claim 11, wherein the processor is configured to launch the application associated with one of the first set of features, the second set of features, and the third set of features upon detecting the input when the handheld device is in an off-state.

13. The handheld computer of claim 11, wherein the back plate of the second segment includes the first connecting member that slides within the first rail, and the second connecting member that slides within the second rail.

14. A handheld device comprising:
a first segment;
a second segment moveably connected to the first segment;
a plurality of exterior surfaces provided by the first segment and the second segment;
a plurality of hardware devices disposed on the plurality of exterior surfaces;
a processor configured to execute a plurality of applications, including at least a first application associated with a first set of hardware devices in the plurality of hardware devices, and a second application associated with a second set of hardware devices in the plurality of hardware devices;
wherein the handheld device is configured to be held by a user so as to orient one of the plurality of exterior surfaces towards the user, and
wherein the first segment and the second segment can be positioned so that a first exterior surface in the plurality of exterior surfaces can be oriented towards the user so as to favor the use of the first set of hardware devices in conjunction with execution of the first application, and a second exterior surface in the plurality of exterior surfaces can be oriented towards the user so as to favor the use of the second set of hardware devices in conjunction with execution of the second application.

15. The handheld device of claim 14, wherein the first application corresponds to an audio application, and the first set of hardware devices includes at least one of a microphone and a speaker.

16. The handheld device of claim 14, wherein the second application corresponds to a camera application, and the second set of hardware devices includes a lens.

17. The handheld device of claim 14, further comprising a display and a set of actuation keys provided on a third exterior surface in the plurality of exterior surfaces, and wherein the processor is configured to associate one or more of the actuation keys with one of the applications in the plurality of applications.

18. The handheld device of claim 17, wherein the processor is configured to detect an input entered through one of the first set of hardware devices, the second set of hardware devices, or through actuation of one of the one or more actuation keys, and wherein if the handheld device is in an off-state, to switch to an operable state and automatically launch the application associated with the one of the first set of hardware devices, the second set of hardware devices, or the actuated one of the one or more actuation keys.

19. The handheld device of claim 17, wherein the processor is configured to detect an input entered through one of the first set of hardware devices, the second set of hardware devices, or through actuation of one of the one or more actuation keys, and wherein if the handheld device is executing an existing application not associated with the first set of hardware devices, the second set of hardware devices, or the actuated one or more actuation keys that is used to enter the input, then the processor is configured to stop executing the existing application, and launch the application associated with the one of the first set of hardware devices, the second set of hardware devices, or the actuated one of the one or more actuation keys.

20. The handheld device of claim 14, wherein the first application and the second application are each automatically executed in response to the processor detecting a relative orientation of the first segment and the second segment.
